(19) United States
(12) Patent Application Publication
(10) Pub. No.: US 2026/0068031 A1
(43) Pub. Date: Mar. 5, 2026

(54) ELECTRONIC DEVICE

(71) Applicant: Samsung SDI Co., Ltd., Yongin-si (KR)

(72) Inventor: Jiyun CHOI, Yongin-si (KR)

(21) Appl. No.: 19/065,924

(22) Filed: Feb. 27, 2025

(30) Foreign Application Priority Data
Aug. 30, 2024 (KR) 10-2024-0117528

(51) Int. Cl. H05K 1/02; H05K 1/14

(52) U.S. Cl. CPC H05K 1/0209; H05K 1/147; H05K 2201/10037

(57) ABSTRACT

An electronic device includes: a battery to supply power to the electronic device; a circuit board including: an input/output terminal electrically connected to the battery; and a ground terminal different from the input/output terminal; and at least one connector electrically connecting the battery with the circuit board, the at least one connector including a flexible circuit board connected to the input/output terminal of the circuit board, the flexible circuit board including a flexible member. At least a part of the flexible circuit board is connected to the ground terminal.

### CROSS-REFERENCE TO RELATED APPLICATION

The present application claims priority to and the benefit of Korean Patent Application No. 10-2024-0117528, filed on Aug. 30, 2024, in the Korean Intellectual Property Office, the entire disclosure of which is incorporated by reference herein.

### BACKGROUND

### 1. Field

Aspects of embodiments of the present disclosure relate to an electronic device.

### 2. Description of Related Art

Unlike primary batteries that are not designed to be (re) charged, secondary (or rechargeable) batteries are batteries that are designed to be discharged and recharged. Low-capacity secondary batteries are used in portable, small electronic devices, such as smart phones, feature phones, notebook computers, digital cameras, and camcorders, while large-capacity secondary batteries are widely used as power sources for driving motors in hybrid vehicles and electric vehicles and for storing power (e.g., home and/or utility scale power storage). A secondary battery generally includes an electrode assembly composed of a positive electrode and a negative electrode, a case accommodating the same, and electrode terminals connected to the electrode assembly.

During charging or discharging of a secondary battery, heat may be generated in the secondary battery. If a secondary battery is exposed to excessive heat, it may accelerate the degradation of electrode materials thereof, leading to a decrease in a capacity and other overall performance degradation of the secondary battery. Therefore, heat generation reduction in secondary batteries may be desired.

The above information disclosed in this Background section is for enhancement of understanding of the background of the present disclosure, and therefore, it may contain information that does not constitute related (or prior) art.

### SUMMARY

One or more embodiments of the present disclosure may be directed to an electronic device, in which a secondary battery thereof may have reduced heat generation.

These and other aspects and features of the present disclosure will be described in or will be apparent from the following description of embodiments of the present disclosure.

According to one or more embodiments of the present disclosure, an electronic device includes: a battery configured to supply power to the electronic device; a circuit board including: an input/output terminal electrically connected to the battery; and a ground terminal different from the input/output terminal; and at least one connector electrically connecting the battery with the circuit board, the at least one connector including a flexible circuit board connected to the input/output terminal of the circuit board, the flexible circuit board including a flexible member. At least a part of the flexible circuit board is connected to the ground terminal.

In an embodiment, the at least one connector may further include a protection circuit module connected to an electrode tab of the battery, the protection circuit module including a fixing member.

In an embodiment, the flexible circuit board may include a first connecting member and a second connecting member having different polarities from each other.

In an embodiment, the second connecting member may include a laminate of a base film, a copper layer, a copper plating layer, and a coverlay layer.

In an embodiment, the second connecting member may include a branch portion configured to be connected to the ground terminal.

In an embodiment, the branch portion of the second connecting member may not include the coverlay layer.

In an embodiment, the electronic device may further include a conductor configured to connect the branch portion with the ground terminal.

In an embodiment, the conductor may have an adhesive force.

In an embodiment, the flexible circuit board may include a first part parallel to a width direction of the battery, and a second part perpendicular to the first part.

In an embodiment, the branch portion may be located in the second part.

In an embodiment, the flexible circuit board may include a bent portion where the flexible circuit board may be bent.

In an embodiment, the bent portion may be located in the first part.

In an embodiment, the flexible circuit board may include a connecting pin at one end of the flexible circuit board.

In an embodiment, the connecting pin may be connected to the input/output terminal, and another end of the flexible circuit board may be connected to the protection circuit module.

According to one or more embodiments of the present disclosure, an electronic device includes: a battery configured to supply power to the electronic device; a circuit board including: a first input/output terminal and a second input/output terminal electrically connected to the battery; and a first ground terminal and a second ground terminal different from the first input/output terminal and the second input/output terminal; and at least one connector electrically connecting the battery with the circuit board, the at least one connector including: a protection circuit module connected to a terminal of the battery, the protection circuit module including a fixing member; a first flexible circuit board extending from and connected in a first direction from the protection circuit module; and a second flexible circuit board extending from and connected in a second direction opposite to the first direction from the protection circuit module. At least a part of the first flexible circuit board is connected to the first ground terminal, and at least a part of the second flexible circuit board is connected to the second ground terminal.

In an embodiment, the first flexible circuit board may include a first connecting member and a second connecting member having different polarities from each other, the second flexible circuit board may include a third connecting member and a fourth connecting member having different polarities from each other, and each of the second connecting member and the fourth connecting member may include a laminate of a base film, a copper layer, a copper plating layer, and a coverlay layer.

In an embodiment, the second connecting member may include a first branch portion configured to be connected to the first ground terminal, and the first branch portion of the second connecting member may not include the coverlay layer. The fourth connecting member may include a second branch portion configured to be connected to the second ground terminal, and the second branch portion of the fourth connecting member may not include the coverlay layer.

In an embodiment, the electronic device may further include a first conductor having an adhesive force for connecting the first branch portion with the first ground terminal, and a second conductor having an adhesive force for connecting the second branch portion with the second ground terminal.

In an embodiment, the first flexible circuit board may include a first part parallel to a width direction of the battery, and a second part perpendicular to the first part. The second flexible circuit board may include a third part parallel to the width direction of the battery, and a fourth part perpendicular to the third part.

In an embodiment, the first branch portion may be located in the second part, and the second branch portion may be located in the fourth part.

According to some embodiments of the present disclosure, in an electronic device, because at least a part of a flexible circuit board, which is electrically connected to a battery, may be connected to a ground terminal of a circuit board, a current flowing from the battery may be distributed to the ground terminal through at least a part of the flexible circuit board. As such, heat that may be generated in the flexible circuit board during the charging or discharging process of the battery may be dispersed.

However, aspects and features of the present disclosure are not limited to those described above, and other aspects and features not mentioned will be clearly understood by a person skilled in the art from the detailed description, described below.

### BRIEF DESCRIPTION OF DRAWINGS

The following drawings attached to the present specification illustrate embodiments of the present disclosure, and further describe aspects and features of the present disclosure together with the detailed description of the present disclosure. Thus, the present disclosure should not be construed as being limited to the drawings:

FIG. 1 is an exploded perspective view of an electronic device according to an embodiment of the present disclosure.

FIG. 2 is a view illustrating a flexible circuit board according to an embodiment of the present disclosure.

FIG. 3 is a view illustrating a laminated structure of a flexible circuit board according to an embodiment of the present disclosure.

FIG. 4 is a view illustrating a process of bending a flexible circuit board according to an embodiment of the present disclosure.

FIG. 5 is a view illustrating a flexible circuit board that is bent and connected to an electronic device according to an embodiment of the present disclosure.

FIG. 6 is a view illustrating a connector according to an embodiment of the present disclosure.

FIG. 7 is a view illustrating an electronic device connected to a connector according to an embodiment of the present disclosure.

FIG. 8 is a view illustrating a battery according to an embodiment of the present disclosure.

FIG. 9 is a view illustrating a battery including an electrode assembly inserted therein according to an embodiment of the present disclosure.

FIG. 10 is a view illustrating a battery and a protection circuit module according to an embodiment of the present disclosure.

### DETAILED DESCRIPTION

Hereinafter, embodiments of the present disclosure will be described, in detail, with reference to the accompanying drawings. The terms or words used in the present specification and claims are not to be limitedly interpreted as general or dictionary meanings and should be interpreted as meanings and concepts that are consistent with the technical idea of the present disclosure on the basis of the principle that an inventor can be his/her own lexicographer to appropriately define concepts of terms to describe his/her invention in the best way.

The embodiments described in this specification and the configurations shown in the drawings are only some of the embodiments of the present disclosure and do not represent all of the technical spirit, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may be disposed in contact with the upper (or lower) surface of the element, and another element may also be interposed between the element and the arbitrary element disposed on (or under) the element.

In addition, it will be understood that when a component is referred to as being “linked,” “coupled,” or “connected” to another component, the elements may be directly “coupled,” “linked” or “connected” to each other, or another component may be “interposed” between the components”.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

In this specification, singular expressions include plural expressions unless the context clearly specifies that they are singular. Additionally, plural expressions include singular expressions unless the context clearly specifies that they are plural. Also, throughout the specification, when an element is referred to as “including” an element, it is understood that the element may include other elements as well unless specifically stated otherwise.

In the present disclosure, the sizes and relative sizes of layers and regions illustrated in the drawings may be exaggerated for clarity of illustration. In other words, the sizes shown in the drawings are provided for convenience of illustration, and the present disclosure is not limited to the specific examples shown therein. Additionally, identical reference numerals refer to identical components throughout the present disclosure, unless the context clearly indicates otherwise.

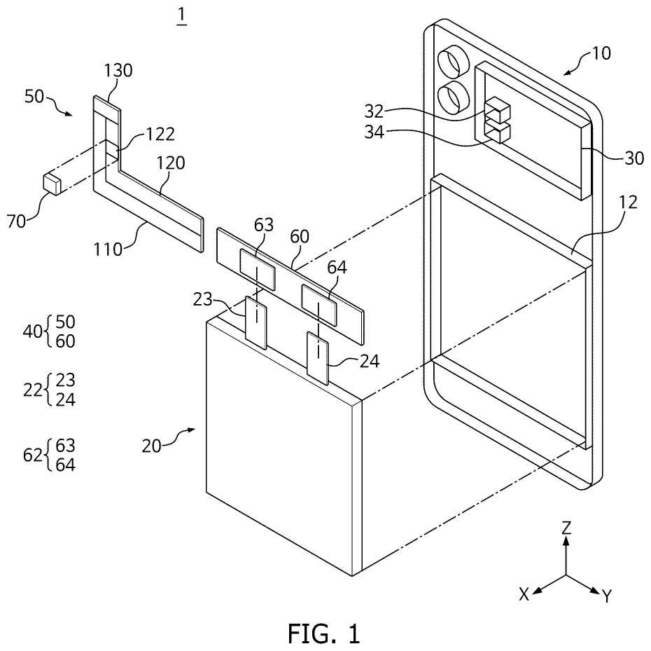

FIG. 1 is an exploded perspective view of an electronic device according to an embodiment of the present disclosure.

Referring to FIG. 1, an electronic device 1 according to an embodiment of the present disclosure may include a battery 20 that supplies power to the electronic device 1, a circuit board 30 electrically connected to the battery 20, and at least one connector 40 that electrically connects the battery 20 to the circuit board 30.

In an embodiment, the electronic device 1 may include a cover 10 accommodating components included in the electronic device 1. As illustrated in FIG. 1, the cover 10 may accommodate the battery 20, the circuit board 30, and the connector 40. In more detail, the cover 10 may include a battery accommodation space 12. Accordingly, the battery 20 may be accommodated in the battery accommodation space 12 of the cover 10. The cover 10 illustrated in FIG. 1 has a shape similar to that of a mobile phone, but the present disclosure is not limited thereto, and the electronic device 1 may be any suitable kind of electronic device. For example, the electronic device 1 according to some embodiments of the present disclosure may correspond to various other suitable electronic devices, such as a camera, a laptop computer, and a tablet PC.

In an embodiment, the battery 20 may include an electrode tab 22 extending in a first direction (e.g., the Z direction of FIG. 1). The battery 20 may be electrically connected to an external component through the electrode tab 22, and may supply power to the external component.

In an embodiment, the circuit board 30 may include an input/output terminal 32 and a ground terminal 34. For example, the circuit board 30 may be a printed circuit board (PCB). The input/output terminal 32 may serve as a passage for receiving an electrical signal from an external component on the circuit board 30, or transmitting an electrical signal to the external component. A positively charged (+) conducting wire may be connected to the input/output terminal 32. The ground terminal 34 may play a role in protecting the circuit board 30 by dispersing current and/or heat from the circuit board 30. A negatively charged (−) conducting wire may be connected to the ground terminal 34. However, the roles of the input/output terminal 32 and the ground terminal 34 are not limited to those described above. In addition, the present disclosure is not limited to the positions of the input/output terminal 32 and the ground terminal 34 illustrated in FIG. 1.

In an embodiment, the connector 40 may include a flexible circuit board 50 that is connected to the input/output terminal 32 of the circuit board 30 and includes a flexible member. The flexible circuit board 50 may correspond to a flexible printed circuit board (FPCB). Because the flexible circuit board 50 includes the flexible member, the flexible circuit board 50 may be bent by a force applied from the outside.

In an embodiment, at least a part of the flexible circuit board 50 may be connected to the ground terminal 34. The part of the flexible circuit board 50, which forms a part of the connector 40, may be connected to the ground terminal 34 so that a current flowing from the battery 20 may be distributed to the ground terminal 34 through at least the part of the flexible circuit board 50. As such, heat that may be generated during the charging or discharging process of the battery 20 may be dispersed.

In an embodiment, the flexible circuit board 50 may include a first connecting member 110 and a second connecting member 120 having different polarities from each other. The first connecting member 110 may be associated with the positive pole ((+) pole), and the second connecting member 120 can be associated with the negative pole ((−) pole).

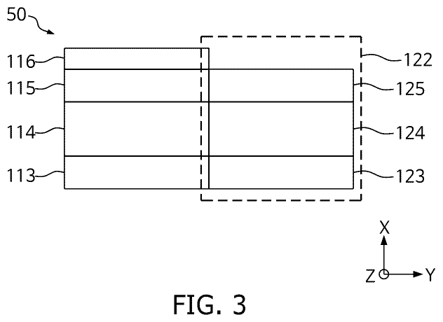

In an embodiment, the second connecting member 120 may include a branch portion 122 for connection to the ground terminal 34. The branch portion 122 may correspond to a part of the second connecting member 120, from which a coverlay layer has been removed, as will be described in more detail below with reference to FIG. 3. Additionally, the second connecting member 120 may be electrically connected to the ground terminal 34 through the branch portion 122. As described above, the battery 20 is electrically connected to the connector 40, and the second connecting member 120, which forms a part of the flexible circuit board 50 included in the connector 40, is electrically connected to the ground terminal 34 through the branch portion 122, so that the battery 20 may be electrically connected to the ground terminal 34. As such, the current flowing from the battery 20 may be distributed to the ground terminal 34, and the heat that may be generated during the charging or discharging process of the battery 20 may be dispersed.

In an embodiment, the connector 40 may further include a protection circuit module (e.g., a protection circuit or a protection circuit device) connected to the electrode tab 22 of the battery 20. The protection circuit module may include a fixing member. The protection circuit module may be a Protection Circuit Module (PCM). The protection circuit module 60 may play a role in protecting and managing the battery 20 by blocking an overcharge, an overdischarge, an overcurrent, and/or the like of the battery 20 in advance. The protection circuit module 60 may include an electrode terminal 62. The electrode terminal 62 of the protection circuit module 60 may be connected to the electrode tab 22 of the battery 20. Accordingly, the battery 20 and the connector 40 may be electrically connected to each other through the electrode terminal 62 of the protection circuit module 60. Additionally, when the protection circuit module 60 and the battery 20 are combined with (e.g., coupled to or attached to) each other, the electrode terminal 62 of the protection circuit module 60 and the electrode tab 22 of the battery 20 may be disposed at corresponding positions. For example, the first electrode terminal 63 may be disposed at a position corresponding to the first electrode tab 23, and the second electrode terminal 64 may be disposed at a position corresponding to the second electrode tab 24.

An electronic device 1 according to an embodiment of the present disclosure may further include a conductor 70. The conductor 70 may play a role of connecting the branch portion 122 to the ground terminal 34. Accordingly, the branch portion 122 of the second connecting member 120 may be electrically connected to the ground terminal 34 through the conductor 70. Additionally, the conductor 70 may have an adhesive strength. Accordingly, the conductor 70 may be bonded onto the branch portion 122 of the second connecting member 120. Additionally, the size of the conductor 70 may be smaller than the size of the branch portion 122 of the second connecting member 120, but the present disclosure is not limited thereto.

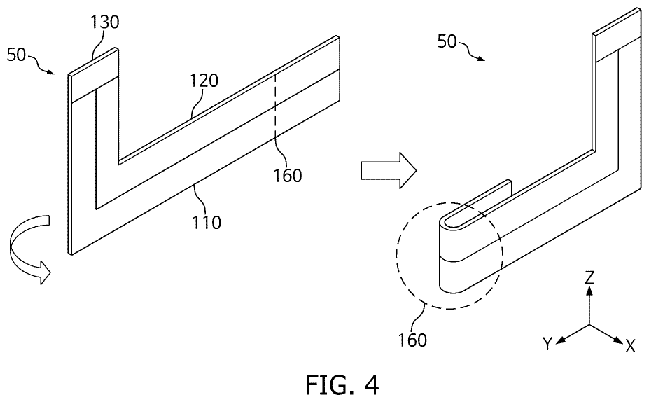

In an embodiment, the flexible circuit board 50 may include a connecting pin 130 disposed at one end of the flexible circuit board 50. As illustrated in FIG. 1, the other end (e.g., an opposite end) of the flexible circuit board 50, which is opposite to the one end of the flexible circuit board 50 where the connecting pin 130 is disposed, may be connected to the protection circuit module 60. The connecting pin 130 may be formed at a position corresponding to the input/output terminal 32 when the flexible circuit board 50 is bent, as will be described in more detail below with reference to FIG. 4. Accordingly, the connecting pin 130 may be connected to the input/output terminal 32, and the flexible circuit board 50 may be connected to the circuit board 30 through the connecting pin 130 and the input/output terminal 32.

In secondary batteries, the heat generated during charging or discharging may cause a decline in the overall performance of the secondary battery. Additionally, in electronic devices powered by the secondary batteries, the flexible circuit board may be a part that generates the most heat during the charging or discharging process of the secondary battery. According to some embodiments of the present disclosure, in the electronic device 1, because at least a part of the flexible circuit board 50, which is electrically connected to the battery 20, is connected to the ground terminal 34 of the circuit board 30, a current flowing from the battery 20 may be distributed to the ground terminal 34 through at least the part of the flexible circuit board 50. As such, heat that may be generated in the flexible circuit board 50 during the charging or discharging process of the battery 20 may be dispersed.

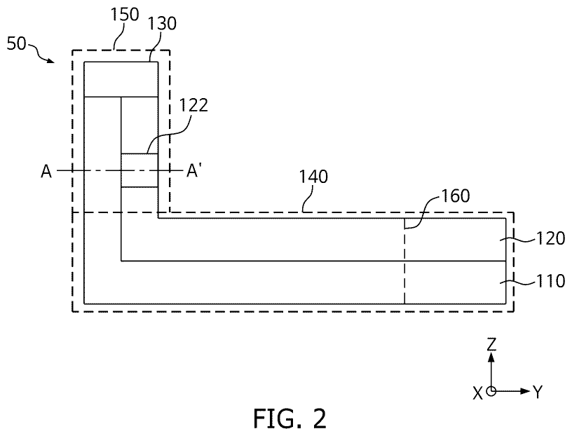

FIG. 2 is a view illustrating a flexible circuit board according to an embodiment of the present disclosure. FIG. 2 may be a view of the flexible circuit board 50 in the X direction (e.g., a plan view).

As illustrated in FIG. 2, the flexible circuit board 50 may include a first connecting member 110 and a second connecting member 120. Additionally, the flexible circuit board 50 may include a branch portion 122 disposed on the second connecting member 120 for a connection to a ground terminal (e.g., the ground terminal 34 of FIG. 1). Further, the flexible circuit board 50 may include a connecting pin 130 disposed at one end of the flexible circuit board 50.

In an embodiment, the flexible circuit board 50 may include a first part 140 disposed parallel to or substantially parallel to the width direction of a battery (e.g., the battery 20 of FIG. 1), and a second part 150 disposed perpendicular to or substantially perpendicular to the first part 140. The width direction of the battery may be the Y direction. In other words, the first part 140 may correspond to a part disposed parallel to or substantially parallel to the Y direction, and the second part 150 may correspond to a part disposed parallel to or substantially parallel to the Z direction, which is perpendicular to or substantially perpendicular to the first part 140.

In an embodiment, the branch portion 122 may be disposed in the second part 150. Referring to FIG. 1, the branch portion 122 may be disposed at a part corresponding to the circuit board 30 when the flexible circuit board 50 is bent. In more detail, the branch portion 122 may be disposed at a part corresponding to the ground terminal 34 of the circuit board 30 when the flexible circuit board 50 is bent. Accordingly, the flexible circuit board 50 may be connected to the ground terminal 34 through the branch portion 122.

In an embodiment, the flexible circuit board 50 may include a bent portion 160 where the flexible circuit board 50 is bent. As described above, because the flexible circuit board 50 includes a flexible member, the flexible circuit board 50 may be bent. The bent portion 160 may be disposed in the first part 140. As the bent portion 160 is disposed in the first part 140 that is disposed parallel to or substantially parallel to the width direction of the battery, the flexible circuit board 50 may be bent parallel to or substantially parallel to the width direction of the battery. As such, when the flexible circuit board 50 is bent, the second portion 150 of the flexible circuit board 50 may be disposed in a part corresponding to the circuit board 30.

FIG. 3 is a view illustrating a laminated structure of a flexible circuit board according to an embodiment of the present disclosure. FIG. 3 may be a cross-sectional view taken along the line A-A′ of FIG. 2.

In an embodiment, the flexible circuit board 50 may be formed by laminating a base film, a copper layer, a copper plating layer, and a coverlay layer. Accordingly, each of the first connecting member (e.g., the first connecting member 110 of FIG. 2) and the second connecting member (e.g., the second connecting member 120 of FIG. 2) constituting the flexible circuit board 50 may be formed by laminating the base film, the copper layer, the copper plating layer, and the coverlay layer.

In the laminated form illustrated in FIG. 3, the left portion of a center line may correspond to the laminated cross-section of the first connecting member, and the right portion of the center line may correspond to the laminated cross-section of the portion included in the branch portion 122 of the second connecting member. As illustrated, the first connecting member may be formed by laminating a first base film 113, a first copper layer 114, a first copper plating layer 115, and a first coverlay layer 116. Additionally, the coverlay layer 116 may be removed from a part of the second connecting member, which is included in the branch portion 122. Accordingly, the part included in the branch portion 122 of the second connecting member may be formed by laminating a second base film 123, a second copper layer 124, and a second copper plating layer 125.

The coverlay layer 116 included in the flexible circuit board 50 may block the copper layer 114/124 or copper plating layer 115/125 from being connected to an external component, thereby preventing a current leakage and the like, and protecting the flexible circuit board 50 from the outside. According to some embodiments of the present disclosure, the flexible circuit board 50 may be electrically connected to an external component through the branch portion 122 by removing the coverlay layer 116 of a part which belongs to the branch portion 122. Accordingly, as described above with reference to FIG. 1, as the branch portion 122 of the flexible circuit board 50 electrically connected to the battery 20 is connected to the ground terminal 34 of the circuit board 30, the current flowing from the battery 20 may be distributed to the ground terminal 34 through the branch portion 122 of the flexible circuit board 50. As such, heat that may be generated in the flexible circuit board 50 during the charging or discharging process of the battery 20 may be dispersed.

FIG. 4 is a view illustrating a process of bending a flexible circuit board according to an embodiment of the present disclosure. FIG. 4 illustrates the flexible circuit board before and after being bent according to some embodiments of the present disclosure.

In an embodiment, the flexible circuit board 50 may include a first connecting member 110 and a second connecting member 120. Further, the flexible circuit board 50 may include a connecting pin 130 disposed at one end of the flexible circuit board 50.

In an embodiment, the flexible circuit board 50 may include a first part disposed parallel to or substantially parallel to the width direction of a battery (e.g., the battery 20 of FIG. 1), and a second part disposed perpendicular to or substantially perpendicular to the first part. The width direction of the battery may be the Y direction. Accordingly, the first part may correspond to a part disposed parallel to or substantially parallel to the Y direction, and the second part may correspond to a part disposed parallel to or substantially parallel to the Z direction, which is perpendicular to or substantially perpendicular to the first part.

In an embodiment, the flexible circuit board 50 may include a bent portion 160 where the flexible circuit board 50 is bent. As described above, because the flexible circuit board 50 includes a flexible member, the flexible circuit board 50 may include the bent portion 160, which is a portion where the flexible circuit board 50 is bent. The bent portion 160 may be disposed in the first part. As the bent portion 160 is disposed in the first part disposed parallel to or substantially parallel to the width direction of the battery, the flexible circuit board 50 may be bent parallel to or substantially parallel to the width direction of the battery. Additionally, as illustrated in FIG. 4, as the flexible circuit board 50 is bent, a surface may be formed, where at least a part of the first connecting member 110 contacts at least a part of the second connecting member 120. In addition, because the flexible circuit board 50 is bent, the flexible circuit board 50 may be easily inserted in a limited internal space of the electronic device 1, and may serve as a passage for electrical connection.

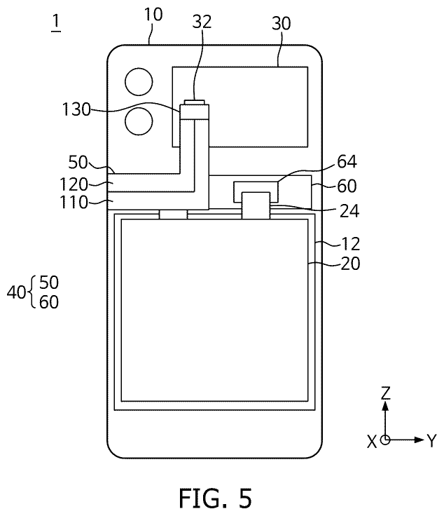

FIG. 5 is a view illustrating a flexible circuit board that is bent and connected to an electronic device according to an embodiment of the present disclosure. FIG. 5 may be a view of an electronic device 1 in the X direction (e.g., a plan view). As illustrated in FIG. 5, the cover 10 of the electronic device 1 may accommodate a battery 20, a circuit board 30, and a connector 40.

In an embodiment, the cover 10 may include a battery accommodation space 12. Accordingly, the battery 20 may be accommodated in the battery accommodation space 12 of the cover 10. The battery 20 may include an electrode tab 24 extending in a first direction (e.g., the Z direction of FIG. 5). The battery 20 may be electrically connected to an external component through the electrode tab 24, and may supply a power to the external component. The circuit board 30 may include an input/output terminal 32 and a ground terminal. As described above, the input/output terminal 32 may be connected to a connecting pin 130 disposed at one end of the flexible circuit board 50, and the ground terminal may be connected to the branch portion of the flexible circuit board 50. The connector 40 may include the flexible circuit board 50 including a flexible member, and a protection circuit module (e.g., a protection circuit or a protection circuit device) 60 including a fixing member.

In an embodiment, the flexible circuit board 50 may be connected to the input/output terminal 32 of the circuit board 30 through the connecting pin 130 disposed at one end of the flexible circuit board 50, and the other end (e.g., an opposite end) of the flexible circuit board 50 may be connected to the protection circuit module 60. In the electronic device 1 illustrated in FIG. 5, the flexible circuit board 50 may be bent in the width direction (e.g., the Y direction) of the battery 20. Accordingly, at least a part of the flexible circuit board 50 may cover at least a part of the protection circuit module 60.

In an embodiment, the flexible circuit board 50 may include a first connecting member 110 and a second connecting member 120 having different polarities from each other. The first connecting member 110 may be associated with the positive (+) pole, and the second connecting member 120 may be associated with the negative (−) pole.

In an embodiment, the second connecting member 120 may include a branch portion for a connection to the ground terminal. The branch portion may correspond to a part of the second connecting member 120, from which the coverlay layer has been removed. A conductor having an adhesive strength may be adhered to the branch portion. Thus, the second connecting member 120 may be electrically connected to the ground terminal through the branch portion and the conductor. The branch portion may be disposed at a position corresponding to the ground terminal, so that the branch portion may be connected to the ground terminal when the flexible circuit board 50 is bent.

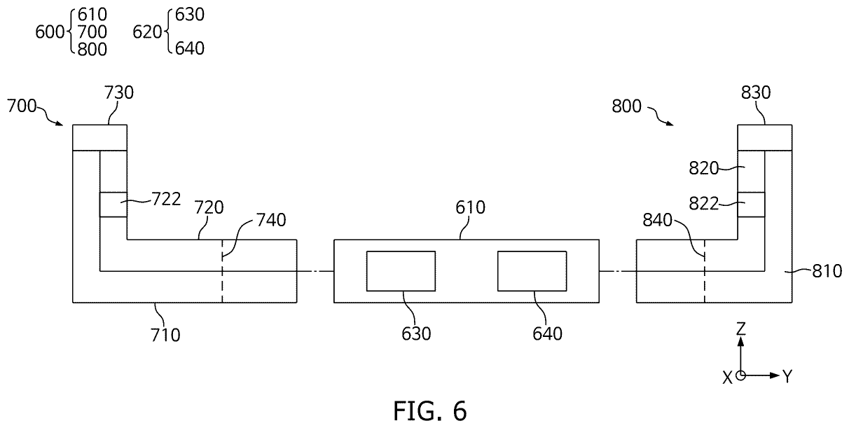

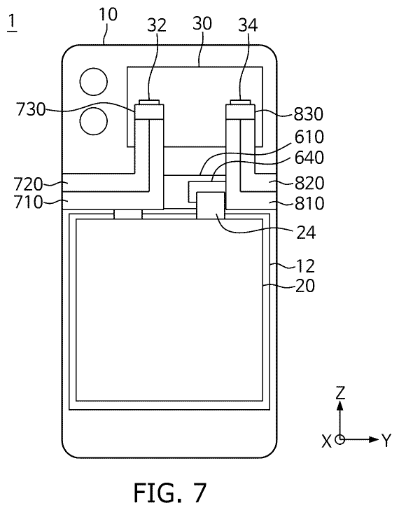

FIG. 6 is a view illustrating a connector according to an embodiment of the present disclosure. FIG. 7 is a view illustrating an electronic device connected to a connector according to an embodiment of the present disclosure. The connector 600 and the electronic device 1 illustrated in FIGS. 6 and 7 may further include a second flexible circuit board 800, compared to the connector 40 and the electronic device 1 described above with reference to FIGS. 1 to 5. The other parts shown in FIGS. 6 and 7 may be the same or substantially the same as those described above with reference to FIGS. 1 to 5, and thus, redundant description thereof may not be repeated.

In an embodiment, the connector 600 may include a second flexible circuit board 800. The second flexible circuit board 800 may be extended and connected from a protection circuit module 610 in a direction opposite to the direction in which a first flexible circuit board 700 is extended and connected from the protection circuit module 610. Accordingly, as illustrated in FIG. 6, each of the first flexible circuit board 700 and the second flexible circuit board 800 may be connected to a corresponding one of the two ends (e.g., opposite ends) of the protection circuit module 610.

In an embodiment, the second flexible circuit board 800 may include a third connecting member 810 and a fourth connecting member 820 having different polarities from each other. The third connecting member 810 may be associated with the positive (+) pole, and the fourth connecting member 820 may be associated with the negative (−) pole. Additionally, the fourth connecting member 820 may include a second branch portion 822 for a connection to a second ground terminal. The second branch portion 822 may correspond to a part of the fourth connecting member 820, from which the coverlay layer has been removed. A second conductor having an adhesive force may be adhered to the second branch portion 822. Accordingly, the fourth connecting member 820 may be electrically connected to the second ground terminal through the second branch portion 822 and the second conductor. The second branch portion 822 may be disposed at a position corresponding to the second ground terminal, so that the second branch portion 822 may be connected to the second ground terminal when the second flexible circuit board 800 is bent.

In an embodiment, the second flexible circuit board 800 may include a second connecting pin 830 disposed at one end of the second flexible circuit board 800. As illustrated in FIG. 6, the other end (e.g., an opposite end) of the second flexible circuit board 800, which is opposite to the one end of the second flexible circuit board 800 where the second connecting pin 830 is disposed, may be connected to the protection circuit module 610. The second connecting pin 830 may be formed at a position corresponding to the second input/output terminal 34 when the second flexible circuit board 800 is bent. Accordingly, the second connecting pin 830 may be connected to the second input/output terminal 34, and the second flexible circuit board 800 may be connected to the circuit board 30 through the second connecting pin 830 and the second input/output terminal 34.

In an embodiment, the second flexible circuit board 800 may include a second bent portion 840 where the second flexible circuit board 800 is bent. As described above, because the second flexible circuit board 800 includes a flexible member, the second flexible circuit board 800 may be bent. The second flexible circuit board 800 may be bent in a direction parallel to or substantially parallel to the width direction (e.g., the Y direction) of the battery 20. As such, when the second flexible circuit board 800 is bent, the second connecting pin 830 of the second flexible circuit board 800 may be disposed at a part corresponding to the second input/output terminal 34 of the circuit board 30.

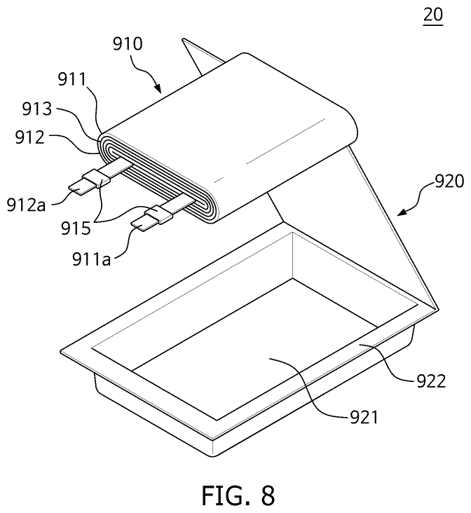

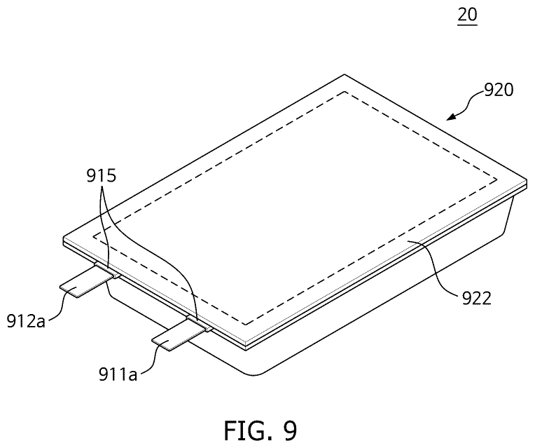

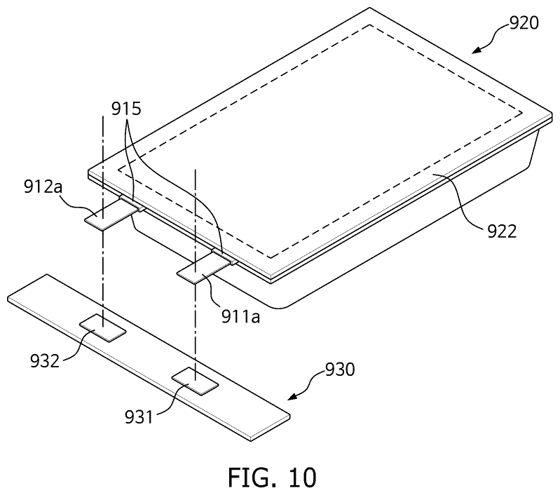

FIG. 8 is a view illustrating a battery according to an embodiment of the present disclosure. FIG. 9 is a view illustrating a battery including an electrode assembly inserted therein according to an embodiment of the present disclosure. FIG. 10 is a view illustrating a battery and a protection circuit module according to an embodiment of the present disclosure.

Hereinafter, for convenience of illustration, a pouch-kind of battery 20 according to some embodiments of the present disclosure may be described in more detail with reference to FIGS. 8 to 10, but the present disclosure is not limited to the pouch-kind of battery.

Referring to FIGS. 8 to 10, a battery 20 according to an embodiment of the present disclosure may include an electrode assembly 910 and a case 920.

According to an embodiment, the electrode assembly 910 may include a first electrode plate 911, a second electrode plate 912, and a separator 913. The first electrode plate 911 may be a negative electrode plate, and the second electrode plate 912 may be a positive electrode plate. As another example, the first electrode plate 911 may be a positive electrode plate and the second electrode plate 912 may be a negative electrode plate.

According to an embodiment, the electrode assembly 910 may be formed by winding or laminating the first electrode plate 911, the separator 913, and the second electrode plate 912, which are formed in a thin plate shape or film shape. When the electrode assembly 910 is a wound laminate, a winding axis may be parallel to or substantially parallel to a long axis direction of the case 920. In addition, the electrode assembly 910 may be a stack kind rather than a winding kind, and the shape of the electrode assembly 910 is not particularly limited.

According to an embodiment, the first electrode plate 911 may be formed by applying an active material, such as graphite or carbon, to a current collector plate formed of a metal foil, such as copper, a copper alloy, nickel, or a nickel alloy. The first electrode plate 911 may include a first non-coated portion, which is an area where no active material is applied. The first non-coated portion may be connected to a separately formed first electrode tab 911a, or the first electrode tab 911a may be formed as a part of the first non-coated portion that is punched out.

According to an embodiment, the second electrode plate 912 may be formed by applying an active material, such as a transition metal oxide, to a current collector plate formed of a metal foil, such as aluminum or an aluminum alloy. The second electrode plate 912 may include a second non-coated portion, which is an area where no active material is applied. The second non-coated portion may be connected to a separately formed second electrode tab 912a, or a part of the second non-coated portion may be punched to form the second electrode tab 912a.

According to an embodiment, the separator 913 may be disposed between the first electrode plate 911 and the second electrode plate 912. The separator 913 may insulate the first electrode plate 911 and the second electrode plate 912 from each other, and may allow lithium ions to be exchanged between the first electrode plate 911 and the second electrode plate 912. The separator 913 may have a sufficient length to completely insulate a space between the first electrode plate 911 and the second electrode plate 912, even if the electrode assembly 910 shrinks or expands during the charging and discharging process of the battery 20.

According to an embodiment, the first electrode tab 911a and the second electrode tab 912a may be provided on one side of the electrode assembly 910. The first electrode tab 911a and the second electrode tab 912a correspond to the first electrode plate 911 and the second electrode plate 912, respectively, and may protrude to one side from the first electrode plate 911 and the second electrode plate 912, respectively. The first electrode tab 911a may be electrically connected to the first electrode, and the second electrode tab 912a may be electrically connected to the second electrode.

According to an embodiment, a film portion 915 may be provided on each of the first electrode tab 911a and the second electrode tab 912a. The film portion 915 may be provided on one surface of the first electrode tab 911a and the second electrode tab 912a, or may cover two surfaces of the first electrode tab 911a and the second electrode tab 912a. The film portion 915 may prevent a short circuit as the first electrode tab 911a and the second electrode tab 912a come into contact with the metal layer exposed at the cross-section of the sealing portion 922 of the case 920. The film portion 915 may be thermally fused with the sealing portion 922 to tightly couple the first electrode tab 911a and the second electrode tab 912a with the sealing portion 922.

In an embodiment, the case 920 may form the exterior of the battery 20. The case 920 may have a cuboid shape as shown in FIGS. 8 to 10, but the present disclosure is not limited thereto.

According to an embodiment, the case 920 may include a receiving portion 921 and a sealing portion 922.

According to an embodiment, the receiving portion 921 has an inner space having dimensions larger than the dimensions of the electrode assembly 910, and may accommodate the electrode assembly 910 and an electrolyte solution. The electrode assembly 901 may be sealed by covering the cover of the case 920 in a state that the electrode assembly 910 is accommodated in the receiving portion 921.

In an embodiment, the sealing portion 922 may be formed along an edge of the case 920. Sealing portions 922 formed on the edge of the case 920 may be sealed by contacting each other in a state in which the electrode assembly 910 is accommodated. In this case, a part of the first electrode tab 911a and the second electrode tab 912a may be exposed to the outside of the case 920, and the film portion 915 may be disposed between the upper and lower portions of the case 920 corresponding to the sealing portion 922.

According to an embodiment, the sealing portion 922 may be made of a heat-fused material, and may have a structure in which heat-fused layers are bonded to each other to be sealed. For example, because the heat-fused material generally has weak adhesion to a metal, the film portion 915 may be attached to the first electrode tab 911a and the second electrode tab 912a in the form of a thin film and fused to the case 920.

According to an embodiment, the protection circuit module 930 may protect the battery cell from an overcharge, an overdischarge, and an overcurrent of the battery 20.

According to an embodiment, the protection circuit module 930 may be electrically connected to the electrode assembly 910. The protection circuit module 930 may be electrically connected to the electrode assembly 910 accommodated in the case 920. As illustrated in FIG. 10, the first electrode terminal 931 and the second electrode terminal 932 of the protection circuit module 930 may be connected to the first electrode tab 911a and the second electrode tab 912a, respectively, which are exposed to the outside of the case 920.

Some embodiments of the present disclosure have been described for purposes of illustration, but those having ordinary skill in the art will be able to make various modifications, changes, and additions within the spirit and scope of the present disclosure, and such modifications, changes, and additions should be considered as falling within the scope of the present disclosure.

Those having ordinary skill in the art will appreciate that various substitutions, modifications, and changes may be made without departing from the spirit and scope of the present disclosure, and therefore the present disclosure is not limited to the above-described embodiments and the illustrated drawings.

Although the present disclosure has been described above with respect to embodiments thereof, the present disclosure is not limited thereto. Various modifications and variations can be made thereto by those skilled in the art within the spirit of the present disclosure and the equivalent scope of the appended claims.

What is claimed is:

1. An electronic device comprising:
a battery configured to supply power to the electronic device;
a circuit board comprising:
an input/output terminal electrically connected to the battery; and
a ground terminal different from the input/output terminal; and
at least one connector electrically connecting the battery with the circuit board, the at least one connector comprising a flexible circuit board connected to the input/output terminal of the circuit board, the flexible circuit board comprising a flexible member,
wherein at least a part of the flexible circuit board is connected to the ground terminal.

2. The electronic device as claimed in claim 1, wherein the at least one connector further comprises a protection circuit module connected to an electrode tab of the battery, the protection circuit module comprising a fixing member.

3. The electronic device as claimed in claim 1, wherein the flexible circuit board comprises a first connecting member and a second connecting member having different polarities from each other.

4. The electronic device as claimed in claim 3, wherein the second connecting member comprises a laminate of a base film, a copper layer, a copper plating layer, and a coverlay layer.

5. The electronic device as claimed in claim 4, wherein the second connecting member comprises a branch portion configured to be connected to the ground terminal.

6. The electronic device as claimed in claim 5, wherein the branch portion of the second connecting member does not include the coverlay layer.

7. The electronic device as claimed in claim 6, further comprising a conductor configured to connect the branch portion with the ground terminal.

8. The electronic device as claimed in claim 7, wherein the conductor has an adhesive force.

9. The electronic device as claimed in claim 5, wherein the flexible circuit board comprises a first part parallel to a width direction of the battery, and a second part perpendicular to the first part.

10. The electronic device as claimed in claim 9, wherein the branch portion is located in the second part.

11. The electronic device as claimed in claim 9, wherein the flexible circuit board comprises a bent portion where the flexible circuit board is bent.

12. The electronic device as claimed in claim 11, wherein the bent portion is located in the first part.

13. The electronic device as claimed in claim 2, wherein the flexible circuit board comprises a connecting pin at one end of the flexible circuit board.

14. The electronic device as claimed in claim 13, wherein the connecting pin is connected to the input/output terminal, and
wherein another end of the flexible circuit board is connected to the protection circuit module.

15. An electronic device comprising:
a battery configured to supply power to the electronic device;
a circuit board comprising:
a first input/output terminal and a second input/output terminal electrically connected to the battery; and
a first ground terminal and a second ground terminal different from the first input/output terminal and the second input/output terminal; and
at least one connector electrically connecting the battery with the circuit board, the at least one connector comprising:
a protection circuit module connected to a terminal of the battery, the protection circuit module comprising a fixing member;
a first flexible circuit board extending from and connected in a first direction from the protection circuit module; and
a second flexible circuit board extending from and connected in a second direction opposite to the first direction from the protection circuit module,
wherein at least a part of the first flexible circuit board is connected to the first ground terminal, and at least a part of the second flexible circuit board is connected to the second ground terminal.

16. The electronic device as claimed in claim 15, wherein the first flexible circuit board comprises a first connecting member and a second connecting member having different polarities from each other,
the second flexible circuit board comprises a third connecting member and a fourth connecting member having different polarities from each other, and
each of the second connecting member and the fourth connecting member comprises a laminate of a base film, a copper layer, a copper plating layer, and a coverlay layer.

17. The electronic device as claimed in claim 16, wherein the second connecting member comprises a first branch portion configured to be connected to the first ground terminal,
wherein the first branch portion of the second connecting member does not include the coverlay layer,
wherein the fourth connecting member comprises a second branch portion configured to be connected to the second ground terminal, and
wherein the second branch portion of the fourth connecting member does not include the coverlay layer.

18. The electronic device as claimed in claim 17, further comprising a first conductor having an adhesive force for connecting the first branch portion with the first ground terminal, and a second conductor having an adhesive force for connecting the second branch portion with the second ground terminal.

19. The electronic device as claimed in claim 17, wherein the first flexible circuit board comprises a first part parallel to a width direction of the battery, and a second part perpendicular to the first part, and
the second flexible circuit board comprises a third part parallel to the width direction of the battery, and a fourth part perpendicular to the third part.

20. The electronic device as claimed in claim 19, wherein the first branch portion is located in the second part, and the second branch portion is located in the fourth part.
